(19) United States
(12) Patent Application Publication
(10) Pub. No.: US 2018/0218996 A1
(43) Pub. Date: Aug. 2, 2018

(54) Method For Producing Wire Bond Connection And Arrangement For Implementing The Method

(71) Applicant: F&K Delvotec Bondtechnik GmbH, Ottobrunn (DE)

(72) Inventor: Franz Schlicht, Maitenbeth (DE)

(21) Appl. No.: 15/879,981

(22) Filed: Jan. 25, 2018

(30) Foreign Application Priority Data
Jan. 30, 2017 (DE) 10 2017 101 736.4

(51) Int. Cl. H01L 23/00; B23K 20/10

(52) U.S. Cl. CPC H01L 24/78; H01L 24/85; B23K 20/10; H01L 2224/85205; H01L 2224/859; B23K 2201/40; H01L 2224/78343; H01L 2224/78925; H01L 2224/78901; H01L 2224/85801; H01L 2224/8501

(57) ABSTRACT

Method for producing wire bond connections between an electronic component or a module and a substrate with energy input into a bonding wire by an ultrasonic transducer, wherein during the energy input for forming a first wire bond connection, at least one bonding parameter characterizing the instantaneous state of the bonding wire is measured in dependence on time, the curve shape of the time dependence is differentiated by means of predetermined comparative criteria or curves into three curve sections and hereby the temporal course of the method into three phases, to be specific, a cleaning, a fusion and a tempering phase, and the energy fed into the ultrasonic transducer and/or the bonding force exerted on the bonding wire and/or the duration of the energy input into at least one partial section of at least the cleaning and the fusion phase, in particular each of the cleaning, fusion and tempering phases is/are controlled independent of the measurement result in quasi real time during the formation of the first wire bond connection or during the subsequent formation of a second wire bond connection of the same type in dependence on the curve shape in the associated curve section in a phase-specific manner.

The invention relates to a method for producing wire bond connections and an arrangement for implementing the method.

Wire bond connections are employed in great numbers in electronic devices of all kinds for contacting electronic components and especially integrated circuits (chips). The quality of these connections determines the performance and reliability of the respective electronic devices to a considerable extent. Manufacturers of electronic devices therefore pay great attention to quality control, and the manufacturers of wire bonding machines are confronted with requirements for ever more reliable test and process control systems.

One of the most developed and widespread bonding method is the ultrasonic wire bonding (“wedge bonding”) which basically constitutes a micro friction welding technique. In this case—as described in the Applicant's U.S. Pat. No. 4,619,397, for example—an aluminum wire in contact with a substrate surface to which it is to be connected in a material-bonded manner, is subjected to rapid vibration by an ultrasonic transducer and at the same time pressed onto the upper surface. Under the effects of compressive force (bonding force) and vibration energy (bonding energy), an oxide layer situated on the upper surface is broken and a material-bonded boundary layer connection is produced under strong deformation and local heating.

More detailed explanations as to this method may be omitted here since it is very well known to the skilled person for a long time.

For testing the bond connections produced in this manner, a plurality of methods has been established, among which only the method according to the Applicant's U.S. Pat. No. 4,984,730 should be referred to at this point. In this pamphlet, a test method is described which is based on the detection of deformation of the bonding wire during the bonding process and the comparison with a standard or reference curve. Current deformation curves that are too far away from the reference curve are evaluated as an indication of insufficient quality of the wire bond connection, and the detection of such inadmissible deviations gives rise to interrupt the process and newly set relevant process parameters.

An in some terms similar method for testing connections produced by ultrasonic wire bonding is described in DE 44 47 073 C1. Here, the strength of the connection represents a decisive parameter for the bond quality. It is proposed to detect, as the relevant parameter, the velocity and/or the temporal course of the deformation of the bonding wire and the temporal course of the bonding tool amplitude (wedge amplitude) during the bonding operation and to evaluate the same by comparison with reference data, This method enables the strength of each single connection to be tested without any substantial additional time expenditure.

The Applicant's U.S. Pat. No. 5,314,105 describes a system for controlling an ultrasonic wire bonding process, in which the bonding process is controlled in real time or quasi real time based on detecting the time-dependence of the bonding wire deformation. It is especially proposed to keep the energy fed into the ultrasonic transducer at a high level until a strong increase of deformation appears in the curve of time dependence, and then to decrease it to a predetermined lower value. It is moreover proposed—in a preferred proceeding—to turn off the ultrasonic transducer completely when the wire deformation has substantially reached a predetermined final value.

EP 0 275 877 B1 likewise discloses a bonding method in which a sensor system is provided for measuring the bonding force and for measuring the ultrasonic amplitude, and the control of the bonding process is performed in addition by means of the temperature of a component to be bonded.

A more novel approach that is based on that, is described, for example, in EP 2 218 097 B1. This approach uses a piezo sensor already provided in the above-mentioned EP 0 275 877 A to detect a transverse strain perpendicular to the ultrasonic wave. A voltage sensor is in addition employed to detect a voltage curve measurement signal which represents the temporal course of the generator voltage. The piezo sensor signal and the voltage sensor signal are transmitted to a phase comparator, and the phase difference between both of them is detected. A phase regulator (which has the mentioned phase comparator allocated) is intended to reduce the tool vibration frequency at the US generator such that preferably mechanical resonance occurs in the transducer-bonding tool unit. The complete disappearance of the phase difference and thus an ideal resonance, however, are not definitely specified in the main claims.

In embodiments, a “friction value” is determined in the bonding process and utilized for controlling and/or regulating the bonding process (for instance, of bonding force, ultrasonic power, bonding time and/or US frequency), and specifically, an actual temporal course of this friction value is compared to a stored target temporal course, and a quality value characterizing the quality of the bonding operation and/or the bond connection is derived therefrom. This value preferably can be utilized in turn to control subsequent bonding processes. According to the preferred configuration, the bonding device comprises a corresponding storage unit for the target temporal course and a control device which converts the temporal course of the friction value and/or the result of the comparison to the target temporal course in a control or regulating signal.

WO 02/070185 A1 utilizes a plurality of sensors for detecting measurement signals of a plurality of parameters that are variable during the bonding operation to assess the bonding quality and/or to influence the bonding operation. The temporal course of parameters is supposed to be represented and quantities derived from the temporal course be formed and so-called deviating courses be determined by comparison to a respective allocated target course. Moreover, a statistical evaluation is supposed to be performed for the target courses and an implicated confidence consideration be made. Finally, a quality index for the bonding process and/or the bonding connection is obtained from one or more of the deviating courses, and a comprehensive quality index is utilized for controlling the regulation of subsequent bonding processes.

Based on that, EP 2 385 545 B1 teaches for the measurement parameters to comprise at least the velocity of the tool tip und the generator voltage of the US generator, and for the actual courses of the quantities derived from the parameters to comprise at least the mechanical admittance as a quotient of tool velocity and generator voltage. Only the method claim mentions in addition that “one or more” deviating courses “are variably weighted with respect to the different elements of the deviation vector”—whatever that means.

Several dependent claims of the latter publication either specify the temporal courses used and/or deviating courses and the use thereof within a running bonding process or for subsequent bonding processes, wherein “learning phases” and the use of a bonding parameter reference system are also mentioned. It is moreover proposed for parameters such as amperage or wire deformation or ultrasonic frequency and/or resonance frequency to be detected by means of further sensors (method claim) and corresponding sensors be provided, respectively (device claim).

The present invention is based on the object of proposing, with regard to the prior art, a further improved method and a corresponding arrangement for the bonding process control, by means of which in particular substrates having widely different and possibly defective surface qualities can be bonded in satisfactory quality in a reproducible manner.

This object is solved in its method aspect by a method including the features of claim 1, and in its device aspect by a device including the features of claim 12, Appropriate further developments of the inventive idea are subject of the respective dependent claims.

The invention is based on the idea to differentiate in the control of an ultrasonic bonding method the temporal course thereof into three phases, that is an activating phase, a welding phase and a tempering phase, to which purpose the curve shape of the temporal dependence of at least one bonding parameter characterizing the instantaneous state of the bonding wire is utilized. The invention moreover includes the idea to control the energy fed into the ultrasound transducer and/or a bonding force exerted on the bonding wire and/or the duration of the energy input in at least one partial section at least of the activating and welding phases. In particular in each of the activating, welding and tempering phases in quasi real time in dependence on the measurement result. Especially, this may be performed according to the invention in a phase-specific manner either “online” during the formation of the first wire bond connection or during the subsequent formation of a second wire bond connection of the same type in dependence on the curve shape in the curve section allocated to the respective phase.

In particular the duration of the energy input in the activating phase and thus the point of transition to the welding phase are variably controlled in dependence on the curve shape of the temporal course of the at least one bonding parameter. It should be mentioned as a special case that a completion of the energy input after the expiration of a predefined duration as well, and thus a cancellation of the entire bonding operation, is within the scope of the invention insofar as this is controlled in dependence on the detection and analysis of the time dependence of at least one bonding parameter.

In preferred realizations, the or each of the respective controlled bonding parameters is/are set to one of a plurality of prestored values, to each of which a comparative curve shape is allocated in the associated curve section. In this case, that value of the controlled bonding parameter is set whose associated comparative curve shape of the measured value used is closest to the instantaneously detected curve shape in the curve section.

In a variant of the proposed method, the or each of the controlled bonding parameters is/are controlled in the subsequent formation of a second wire bond connection of the same type in the activating, welding and tempering phases thereof in each case in dependence on the associated curve section of the time dependence detected in the formation of the first wire bond connection or at least the time dependence in an observation window.

As already noted, the curve shape may be detected and evaluated alternatively already during the formation of the current (“first”) wire bond connection in an initial partial section of at least one, in particular each of the activating and welding phases, and the evaluation result be immediately utilized in quasi real time to define the or each of the controlled bonding parameters during a subsequent partial section of the respective phase of the formation of the first wire bond connection.

In a further realization of the invention, the evaluation of the curve shape of the overall time dependence for differentiating into the three curve sections and/or the evaluation for defining the values of the or each of the controlled bonding parameters comprises the comparison to at least one further stored overall reference curve, in particular to an array of overall reference curves of an “optimum” bonding process or bonding processes adapted to defined conditions.

In preferred realizations of the invention, the impedance (or the operating current) and optionally the frequency of the ultrasonic transducer and/or a deformation of the bonding wire are measured as the bonding parameter characterizing the state of the bonding wire.

It is especially provided within the scope of the invention that in at least one of the three phases of the process sequence (exclusively or in any case primarily) a selection of bonding parameters characterizing the state of the bonding wire is detected other than in at least another phase and is taken as a basis for the control. In particular in the activating phase, the deformation of the bonding wire and the impedance and, optionally, frequency of the ultrasonic transducer are detected while in the welding phase only the deformation of the bonding wire is detected.

In a particularly preferred configuration, the duration of the activating phase and thus the point of transition to the welding phase is determined primarily based on the evaluation of the wire deformation curve shape, in particular on a comparison thereof to a corresponding reference curve.

In a further configuration, a phase-specific definition of the energy fed into the ultrasonic transducer and of the bonding force is performed for each of the activating, welding and tempering phases. This is in particular achieved in the form of a calculation process executed in quasi real time, or a selection from one of a plurality of prestored sets of control parameters in dependence on the curve shape.

In further realizations of the method, the control of the fed energy and/or the bonding force and/or the duration of the energy input includes at least one regulation component.

The proposed arrangement, on the one hand, is characterized in that an evaluating device for evaluating the bonding parameter time dependence of an evaluating device for evaluating the curve shape of the time dependence of the or each of the measured bonding parameters is present, which comprises a curve shape differentiating device for differentiating the overall time dependence into three curve sections that are different due to a respective characteristic course. Moreover, the arrangement is preferentially characterized in that in a bonding parameter control unit, differentiated sets of control parameters each are stored for the activating, welding and tempering phases of the bonding process for the selection by phases in dependence on initial data of the evaluating device. As an alternative, a calculation unit, that is in particular capable of real time operation, may be provided for the ab initio calculation of the set of control parameters to be applied based on the currently determined time dependence (measurement parameter curve shape) by means of empirical values.

In a realization of the arrangement, the evaluating device includes a reference curve memory for storing reference curves differentiated into the three curve sections and a comparator unit for comparing the curve shape of the current time dependence of the or each of the detected bonding parameters to the reference curves and for outputting data defining the three periods of time.

In a further realization, the bonding parameter control device comprises a feedback member for realizing a regulation component in the control of at least one bonding parameter.

Advantages and utilities of the invention incidentally will arise from the following description of preferred exemplary embodiments and aspects by means of the Figures. Shown are in:

FIG. 1 a schematic representation of a first arrangement for implementing the method according to the invention, in a kind of a functional block diagram,

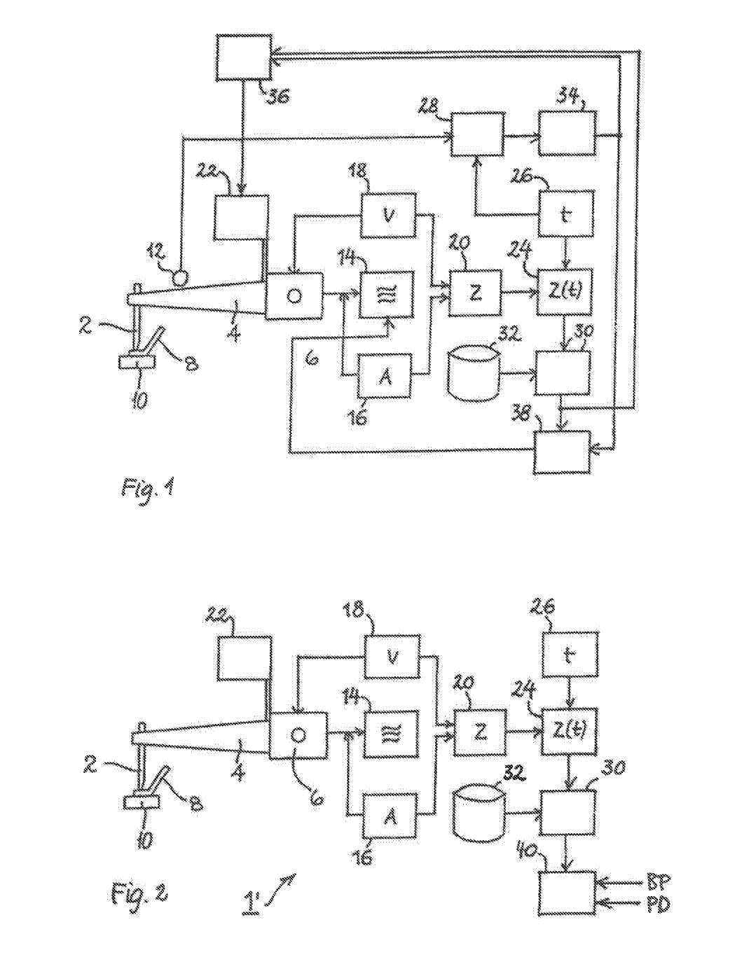

FIG. 2 a schematic representation of a second arrangement for implementing the method according to the invention, in a kind of a functional block diagram, and

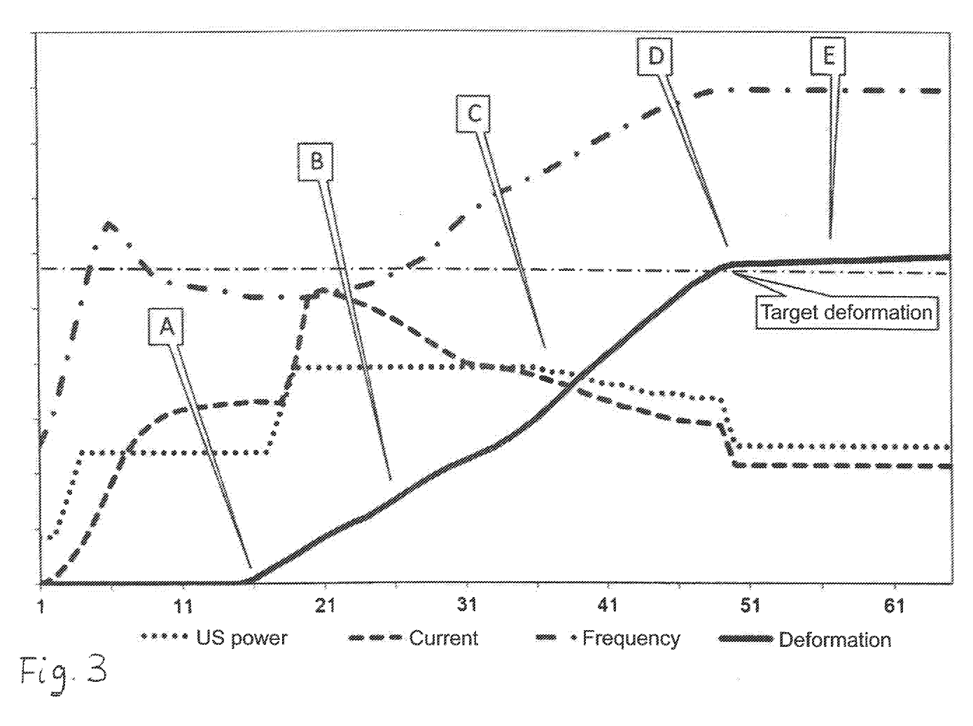

FIG. 3 a schematic graphic representation of the time sequence of a bonding process by means of the relevant measuring and control parameters, respectively.

In the production sequence of a wire bond connection on a contact surface of an electronic component or module, three phases are usually distinguished: (a) a cleaning or activating phase, in which an activation of the boundary surface occurs due to the vibration of the bonding wire generated by means of the ultrasonic transducer on the substrate surface; (b) a phase of the material mixing between bonding wire and material of the contact surface, thus the actual welding (called welding or deformation phase here), and finally (c) a tempering phase, in which the generated weld connection is thermally stabilized. A finer subdivision of the bonding process is possible and even reasonable for certain purposes, however, is not made in the context of the present invention.

While usually each of the three phases is executed with a predefined set of bonding parameters, it is proposed here to control not only in the welding phase but at least also in the preceding activating phase at least a part of the bonding parameters (thus in particular the energy fed into the ultrasonic transducer and/or the bonding force exerted on the bonding wire and/or the duration of the energy input into the bonding wire) in dependence on a state detection of the connection partners or the connection being formed in a manner depending on the measured values, and namely in particular while following the detected time dependence of at least one measurement parameter.

As is generally known, the quality of a wire bond connection depends decisively on the adequate setting of the bonding parameters, and this not only in the welding or deformation phase but also in the activating and tempering phases (in dependence on the condition of the connection partners). Suboptimal surface conditions (oxide coating, contaminations, roughness, local hardening occurrences, etc.) may in particular be “compensated” within certain limits by appropriately setting the bonding parameters such that a high-quality bond connection may be produced.

In a realization of the invention, a rubbing, “scrubbing” relative motion of wire and contact surface is desired in the cleaning or activating phase; so, a high movement amplitude of the wire is set for logical reasons (via a corresponding energy supply to the transducer) and a low bonding force. Hereby, a welding or fusion is initially prevented until an at least locally sufficiently activated boundary surface has formed so that first bonding islands or local welding spots develop. This becomes evident in an increasing damping of the vibration of the bonding wire, metrologically therefore in an increasing impedance (or a decreasing measured current) at the transducer and a rising transducer frequency. At the same time, an initial deformation of the bonding wire takes place which can likewise be detected metrologically. In a manner of proceeding that is advantageous from the current point of view, the ultrasonic power will in this phase be kept at a low to medium value, and the bonding force at a low value.

Once the cleaned and thereby activated opposite surfaces of bonding wire and contact surface begin to join, the relative movement of the contacting surfaces is impeded and a shearing action produced within the bonding wire. This results in a softening of the wire structure; the material flows below the bonding tool. This may be detected metrologically as a significant deformation which can be tracked dependent on time as a “descent” of the wedge. The curve shape of the time dependence of the deformation may be used as a correcting variable. In an advantageous configuration of this phase under normal conditions, the bonding force is increased in a first partial section and the ultrasonic power regulated in such a manner that a predetermined deformation rate is satisfied. In case it is observed that this desirable deformation rate is fallen below or exceeded, the ultrasonic power will be increased or decreased (for example, upward and downward at a determined regulating speed, minimum/maximum regulating amplitude, etc.) in a determined appropriate manner.

With an increasing deformation, a solidification of the wire can occur so that the desired deformation rate might also change. If need be, a switchover to another set of control parameters takes place in a second partial section of the welding phase, wherein a previously defined amount of the wire deformation may be used for this purposes as a switching threshold. Hence, it is also possible to utilize a single absolute or relative value for triggering a control process apart from the curve shape of the temporal course of the deformation (or another measured or set variable). The reaching of a previously defined deformation amount of the bond wire may also be utilized as a trigger for ending the welding phase (by switching to another set of control parameters).

In the tempering phase, a continuous shearing action is exerted on the bonding zone (welding zone) by the ultrasonic vibration, whereby the healing of lattice dislocations and flaws is enabled. For this purpose and in an advantageous way from the current point of view, a lower level of ultrasonic vibration is set and kept constant for a defined time (or else until a defined total bonding process time is reached). The impedance and frequency may be monitored here so as to identify a possible “slipping” of the wedge over the bonding wire surface, which would generate over-bonds or so-called “burnt bonds”, and preferably to suppress it by changing the bonding force and, where appropriate, the ultrasonic amplitude as well. Although basically a fixed predefined set of control parameters could be used in the tempering phase, here as well, a bonding process control depending on measured values could therefore be advantageous.

In realizations of the proposed process sequence, the time dependence of the relevant measurement parameters may be used by means of observation windows in a manner that is sufficient for the process control and is reducing the demands on the processing of measured data. These observation windows may correspond widely to partial sections of the single phases or even may be considerably shorter, and are in particular variably selectable in their position on the time axis. If appropriate, the position may be preselected already at the start of the process based on product data of the bonding wire and/or the condition of the contact surface of the electronic component; however, the position may even be varied in other realizations in dependence on measurement results gained initially in the process.

FIG. 1 schematically illustrates an arrangement 1 for implementing a bonding process which is controlled in dependence on a deformation-time curve and an impedance-time curve, which arrangement is typically integrated in a wire bonder (not shown as a whole). Among the usual components of a wire bonder, a wedge 2 and a horn 4 of an ultrasonic transducer 6 are illustrated, which horn is mounted to the wedge. The wedge serves to produce a bond connection on a substrate 10 by means of a bonding wire 8.

The horn 4 of the ultrasonic transducer 6 has a deformation sensor 12 allocated—that is known per se. In a power supply 14 of the transducer 6, an amperage measuring device 16 and a voltage measuring device 18 are integrated, which, on the output side, are connected to an impedance determining device 20 for calculating instantaneous impedance values. The transducer 6 has a bonding head drive unit 22 allocated which generates a predetermined pressing force (bonding force) the bonding tool 2 exerts on the bonding wire 8. To the output of the impedance determining device 20, an impedance registering device 24 is connected for registering the time dependence of the impedance, which is connected to a timer 26 via a further input. The deformation sensor 12 is connected to the input of a deformation registering device 28 for registering the time dependence of the bonding wire deformation, which likewise receives a time signal from the timer 26.

The impedance registering device 24 is connected to an impedance evaluating device 30 on its output side, which is connected to a reference database 32 via a further input. The output of the deformation registering device 28 is connected to a deformation evaluating device 34. Both evaluating devices 30 and 34 are commonly connected to a bonding force control unit 36, on the one hand, and to a bonding energy control unit 38, on the other. The bonding force control unit 36 acts upon the bonding head drive unit 22 for the fast control of the bonding force, and the bonding energy control unit 38 acts upon the power supply 14 of the transducer 6 for the fast control of the bonding energy (ultrasonic vibration energy).

The functionality of the measuring and control arrangement 1 arises already from the above general explanations to the proposed method and will therefore not be described here again. It is pointed out that evaluating and control algorithms, respectively, are stored in the evaluating devices 30 and 34 and the control units 36 and 38, which are derived from measurement curves of the transducer impedance and wire bond deformation obtained in an experimental way on a plurality of substrates with different bonding wires and process parameter constellations and the associated usual quality analyses. The person skilled in bonding technology is familiar with such measurements and quality analyses so that he will be able to find specific control algorithms for specific components, substrates and bonding wires by himself.

FIG. 2 shows a partial representation of a further testing arrangement Y which is considerably simplified as compared to the measuring and control arrangement 1 according to FIG. 1. In this case, a wire bonder having the usual structure—the bonding tool 2, the horn 4, the transducer 6 and the bonding head drive unit 22 thereof being shown again in the Figure—in addition has the amperage measuring device 16, the voltage measuring device 18 and the impedance determining device 20, as well as the impedance registering device 24 and the impedance evaluating device 30 including the associated database 32. However, the means illustrated in FIG. 1 for detecting and evaluation deformation are not present, and means for the online control of the bonding process are not shown.

Rather it is shown here that the impedance evaluating device 30, on its output side, is connected to a memory device 40′ for storing the temporal course of the impedance. From the control unit (not shown here) of the bonding process, the time dependence of the set bonding parameters, and from the input control, the process-relevant data of the bonded component and the bonding wire are moreover supplied to the memory device 40f, which is symbolized in the Figure by arrows designated by the letters BP and PD. Thus, complete comparative data sets or total reference curves may be stored in the memory device as a basis for future bonding process controls.

The function of this embodiment arises also from the above explanations to the proposed method.

FIG. 3 schematically shows the time dependence of relevant measuring and control parameters of an exemplary bonding process for explaining the proposed method by way of example. The X axis is designated in arbitrary units; the dotted line represents the ultrasonic power, the dashed line the transducer current, (representative of the impedance), the dash-dotted line the ultrasonic frequency, and the solid line the bonding wire deformation. These are not real measurement or control signal curves, but curves smoothed for explanation purposes.

The bonding process starts with an activating and cleaning phase, respectively, wherein a relatively low ultrasonic force is applied to the bonding wire (and via the latter to the underlying substrate). At the point designated by A, deformation of the bonding wire starts, and thereupon, a switchover to the second phase of the bonding process takes place, the welding and fusion phase, respectively. Here, the ultrasonic power is increased, and also the measured current rises rapidly, whereas the deformation of the bonding wire increases essentially linearly. This phase is therefore also referred to as a deformation phase. The point designated by B is in this phase.

In the shown example, a slight reduction of the ultrasonic power takes place at a point C in response to the fact that the course of the deformation curve has deviated from that of the target curve in that the gradient of the actual deformation curve was greater than that of the target deformation curve. Hereby, the further progress of the bonding wire deformation is kept under control until a target deformation is reached at a point D (illustrated in the Figure as a horizontal dash-dotted line).

When this circumstance is identified, the ultrasonic power will de decreased significantly, and the measured current as well decreases accordingly. This represents the transition to the so-called tempering phase in which a thermal post-processing of the welding point or bond is performed at a constant input of ultrasonic energy until the expiration of a predefined maximum period of time.

Incidentally, the implementation of the invention is also possible in a plurality of modifications of the examples shown here and of the aspects of the invention highlighted further above.

1. Method for producing wire bond connections between an electronic component or a module and a substrate with energy input into a bonding wire by an ultrasonic
during the energy input for forming a first wire bond connection, at least one bonding parameter characterizing the instantaneous state of the bonding wire is measured in dependence on time, the curve shape of the time dependence is differentiated by means of predetermined comparative criteria or curves into three curve sections and hereby the temporal course of the method into three phases, to be specific, a cleaning, a fusion and a tempering phase, and
the energy fed into the ultrasonic transducer and/or the bonding force exerted on the bonding wire and/or the duration of the energy input into at least one partial section of at least the cleaning and the fusion phase, in particular each of the cleaning, fusion and tempering phases is/are controlled independent of the measurement result in quasi real time during the formation of the first wire bond connection or during the subsequent formation of a second wire bond connection of the same type in dependence on the curve shape in the associated curve section in a phase-specific manner.

2. Method according to claim 1, wherein the duration of the energy input in the cleaning phase and thus the point of transition to the fusion phase is variably controlled in dependence on the curve shape of the at least one bonding parameter.

3. Method according to claim 1, wherein the or each of the controlled bonding parameters is/are set to one of a plurality of prestored values, to each of which a comparative curve shape is allocated in the associated curve section, wherein that value of the controlled bonding parameter is set whose allocated comparative curve shape is closest to the instantaneously detected curve shape in the curve section.

4. Method according to claim 1, wherein the or each of the controlled bonding parameters is/are controlled in the subsequent formation of a second wire bond connection of the same type in the entire activating, fusion and tempering phases thereof in each case in dependence on at least one partial section of the associated curve section of the time dependence detected in the formation of the first wire bond connection.

5. Method according to anyone of claim 1, wherein during the formation of the first wire bond connection, the curve shape is detected and evaluated in an initial partial section of at least one, in particular each of the cleaning and fusion phases, and the evaluation result is utilized immediately in quasi real time to define the or each of the controlled bonding parameters during a subsequent partial section of the respective phase of the formation of the first wire bond connection.

6. Method according to claim 1, wherein the evaluation of the curve shape of the overall time dependence for differentiating into the three curve sections and/or the evaluation for defining the value of the or each of the controlled bonding parameters comprises the comparison to at least one stored overall reference curve, in particular to an array of overall reference curves.

7. Method according to claim 1, wherein the impedance and optionally the frequency of the ultrasonic transducer and/or a deformation of the bonding wire are measured as the bonding parameter characterizing the state of the bonding wire.

8. Method according to 1, wherein in at least one of the three phases of the process sequence (exclusively or in any case primarily) a selection of bonding parameters characterizing the state of the bonding wire is detected other than in at least another phase and is taken as a basis for the control, wherein in particular in the cleaning phase, the deformation of the bonding wire and the impedance and frequency of the ultrasonic transducer are detected while in the fusion phase the deformation of the bonding wire is detected.

9. Method according to claim 8, wherein the duration of the cleaning phase and thus the point of transition to the fusion phase is determined based on the evaluation of the wire deformation curve shape, in particular on a comparison thereof to a corresponding reference curve.

10. Method according to claim 1, wherein a phase-specific definition of the energy fed into the ultrasonic transducer and of the bonding force is performed for each of the cleaning, fusion and tempering phases, in particular as a calculation process executed in quasi real time, or a selection from one of a plurality of prestored sets of control parameters in dependence on the curve shape.

11. Method according to claim 1, wherein the control of the fed energy and/or the bonding force and/or the duration of the energy input includes at least one regulation component.

12. An arrangement for producing wire bond connections between an electronic component or a module and a substrate with energy input into a bonding wire by an ultrasonic transducer, comprising
at least one measuring device for a bonding parameter characterizing an instantaneous state of the bonding wire,
a registering device connected to an output of the least one measuring device for registering a time dependence of an output signal of the at least one measuring device during a duration of the energy input,
an evaluating device for evaluating a curve shape of the time dependence of the bonding parameter, wherein the evaluating device includes a curve shape differentiating device for differentiating an overall time dependence into three curve sections that are different due to a respective characteristic course, and
a bonding parameter control unit connected to an output of the evaluating device, wherein in the bonding parameter control unit, in particular differentiated sets of control parameters each are stored for the cleaning, fusion and tempering phases of the bonding process for the selection by phases in dependence on initial data of the evaluating device for a phase-specific control of the fed energy and/or the bonding force and/or the duration of the energy input.

13. Arrangement according to claim 12, wherein the evaluating device includes a reference curve memory for storing reference curves differentiated into three curve sections and a comparator unit for comparing the curve shape of the current time dependence of the or each of the detected bonding parameters to the reference curves and for outputting data defining the three periods of time.

14. Arrangement according to claim 12, wherein the bonding parameter control device comprises a feedback member for realizing a regulation component in the control of at least one bonding parameter.

15. Arrangement according to claim 12 further comprising a wire bonder.
